(19) United States
(12) Patent Application Publication
(10) Pub. No.: US 2008/0169548 A1
(43) Pub. Date: Jul. 17, 2008

(54) Semiconductor package having a semiconductor chip in a substrate and method of fabricating the same

(75) Inventor: Hyung-Gil Baek, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 12/000,377

(22) Filed: Dec. 12, 2007

(30) Foreign Application Priority Data
Jan. 16, 2007 (KR) 10-2007-0004852

(51) Int. Cl. H01L 23/488; H01L 21/58

(52) U.S. Cl. 257/686; 438/118; 257/E23.023; 257/E21.505

(57) ABSTRACT

Example embodiments relate to a semiconductor package having a semiconductor chip provided in a substrate and a method of fabricating the same. The semiconductor package may include a semiconductor substrate having a first through hole and a plurality of second through holes spaced apart from the first through hole. A semiconductor chip having a plurality of pads may be disposed in the first through hole. Solder balls electrically connected to the pads may be attached to end portions of the second through holes. A plurality of the above semiconductor substrates may be stacked to form a multi-chip package.

### PRIORITY STATEMENT

This application claims priority under 35 U.S.C. §119 to Korean Patent Application No. 10-2007-0004852, filed Jan. 16, 2007 in the Korean Intellectual Property Office (KIPO), the entire contents of which are incorporated herein by reference.

### BACKGROUND

1. Technical Field

Example embodiments relate to a semiconductor package having a semiconductor chip in a substrate and a method of fabricating the same.

2. Description of the Related Art

As the sizes of portable electronic devices are scaled down, the sizes of semiconductor packages to be mounted in the portable electronic devices have been similarly scaled down. Consequently, a wafer level semiconductor package has been proposed to reduce the size of semiconductor packages. A wafer level semiconductor package may include a wafer having a plurality of semiconductor chips that is diced to provide a semiconductor package of chip size. Solder balls and joints relating thereto may also be provided in the wafer level semiconductor chip package. Additionally, the back of a semiconductor chip may be polished to reduce the thickness of the semiconductor chip. However, a semiconductor chip having a relatively thin thickness may be prone to warping. For example, when a semiconductor package is heated, the difference between the coefficients of thermal expansion of the semiconductor chip and the material adjacent to the semiconductor chip (e.g., PCB) may cause warping of the semiconductor chip having a relatively thin thickness. The difference between the coefficients of thermal expansion may also cause defects in the solder ball joints. Accordingly, the reliability of the semiconductor device may be decreased.

### SUMMARY OF EXAMPLE EMBODIMENTS

Example embodiments provide a semiconductor package that may improve solder ball joint reliability. The semiconductor package may include a semiconductor substrate having a first through hole and a plurality of second through holes spaced apart from the first through hole. The second through holes may surround the first through hole. A semiconductor chip having a plurality of pads may be disposed in the first through hole. Solder balls electrically connected to the pads may be attached to end portions of the second through holes.

The semiconductor package may include conductive layers covering the sidewalls of the second through holes and electrically connected to the pads and the solder balls. The semiconductor package may further include redistribution traces connecting the conductive layers to the pads. Alternatively, the semiconductor package may include bonding wires connecting the conductive layers to the pads. The semiconductor package may include conductive vias filling the second through holes and electrically connected to the pads and the solder balls.

The semiconductor package may include a first thermal insulator interposed between a sidewall of the first through hole and the semiconductor chip. The first thermal insulator may include an adhesive. The adhesive may extend to cover a lower surface of the semiconductor chip.

The semiconductor substrate may include first to fourth sub-substrates surrounding the first through hole, and second thermal insulators interposed between the sub-substrates. Each of the first to fourth sub-substrates may have the second through holes.

Example embodiments provide a semiconductor package that may have solder balls spaced apart from a semiconductor chip. The semiconductor package may include a lower semiconductor substrate having a first lower through hole and a plurality of second lower through holes spaced apart from the first lower through hole. The second lower through holes may be disposed to surround the first lower through hole. A lower semiconductor chip having a plurality of lower pads may be disposed in the first lower through hole. Solder balls electrically connected to the lower pads may be attached to end portions of the second lower through holes.

An upper semiconductor substrate having a first upper through hole and a plurality of second upper through holes spaced apart from the first upper through hole may be stacked on the lower semiconductor substrate. The second upper through holes may be disposed to surround the first upper through hole. An upper semiconductor chip having a plurality of upper pads may be disposed in the first upper through hole. The upper pads may be electrically connected to the solder balls.

Lower conductive layers covering the sidewalls of the second lower through holes may be electrically connected to the lower pads and the solder balls. Upper conductive layers covering the sidewalls of the second upper through holes may be electrically connected to the upper pads. The semiconductor package may further include lower redistribution traces connecting the lower conductive layers to the lower pads. Similarly, the semiconductor package may further include upper redistribution traces connecting the upper conductive layers to the upper pads. The semiconductor package may further include lower bonding wires connecting the lower conductive layers to the lower pads. Similarly, the semiconductor package may further include upper bonding wires connecting the upper conductive layers to the upper pads.

The semiconductor package may include lower conductive vias filling the second lower through holes and electrically connected to the lower pads and the solder balls. Similarly, the semiconductor package may include upper conductive vias filling the second upper through holes and electrically connected to the upper pads and the lower conductive vias. The semiconductor package may further include bumps interposed between and in contact with the upper conductive vias and the lower conductive vias.

The semiconductor package may include a first lower thermal insulator interposed between a sidewall of the first lower through hole and the lower semiconductor chip. The first lower thermal insulator may include a lower adhesive. The lower adhesive may extend to cover a lower surface of the lower semiconductor chip. The semiconductor package may further include a first upper thermal insulator interposed between a sidewall of the first upper through hole and the upper semiconductor chip. The first upper thermal insulator may include an upper adhesive. The upper adhesive may extend to cover a lower surface of the upper semiconductor chip.

The upper semiconductor substrate may include first to fourth upper sub-substrates surrounding the first upper through hole and second upper thermal insulators interposed between the upper sub-substrates. Each of the first to fourth upper sub-substrates may have the second upper through holes. Similarly, the lower semiconductor substrate may include first to fourth lower sub-substrates surrounding the first lower through hole and second lower thermal insulators interposed between the lower sub-substrates. Each of the first to fourth lower sub-substrate may have the second lower through holes.

Example embodiments provide a method of fabricating a semiconductor package that may improve solder ball joint reliability. The method may include preparing a semiconductor substrate. A first through hole penetrating the semiconductor substrate and a plurality of second through holes spaced apart from the first through hole may be formed. The second through holes may be formed to surround the first through hole. A semiconductor chip having a plurality of pads may be provided in the first through hole. Solder balls electrically connected to the pads may be formed at the end portions of the second through holes.

Forming the first through hole and the second through holes may include patterning an upper surface of the semiconductor substrate to form a first trench and second trenches surrounding the first trench. Forming the first through hole and the second through holes may also include polishing a lower surface of the semiconductor substrate so as to expose the first trench and the second trenches.

Prior to polishing the lower surface, a first thermal insulator may be formed to cover the sidewall and bottom of the first trench, and a semiconductor chip may be provided in the first trench. The first thermal insulator may be made of an adhesive. The method may further include forming first conductive layers covering the sidewalls of the second trenches. The method may further include forming second conductive layers filling the second trenches.

The method may further include forming redistribution traces or bonding wires connecting the pads to the first conductive layers. Preparing the semiconductor substrate may include forming first to fourth sub-substrates surrounding the first through hole and forming a second thermal insulator between the sub-substrates. Each of the first to fourth sub-substrates may be formed to have the second through holes.

### BRIEF DESCRIPTION OF THE DRAWINGS

FIG. 1 is a schematic plan view of a wafer used in a method of fabricating a semiconductor package according to example embodiments.

FIG. 2 is a plan view of a semiconductor package according to example embodiments.

FIG. 3 is a cross-sectional view, taken along line I-I′ of FIG. 2, illustrating a semiconductor package according to example embodiments.

FIGS. 4A to 4D are cross-sectional views illustrating methods of fabricating the semiconductor package shown in FIG. 3 according to example embodiments.

FIG. 5 is a cross-sectional view of another semiconductor package according to example embodiments.

FIG. 6 is a cross-sectional view of another semiconductor package according to example embodiments.

FIG. 7 is a cross-sectional view of another semiconductor package according to example embodiments.

FIG. 8 is a cross-sectional view of another semiconductor package according to example embodiments.

### DETAILED DESCRIPTION OF EXAMPLE EMBODIMENTS

It will be understood that when an element or layer is referred to as being “on”, “connected to”, “coupled to”, or “covering” another element or layer, it may be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Example embodiments may be described with reference to the accompanying drawings. In the drawings, the thickness of the layers and/or regions may have been exaggerated for clarity. Additionally, like numbers refer to like elements throughout the specification.

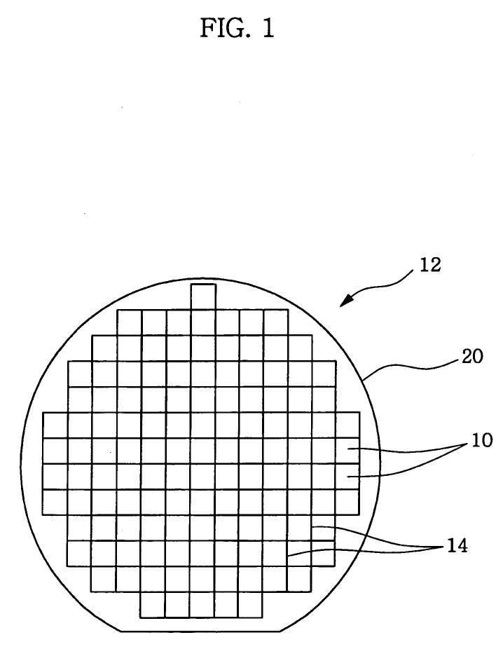

The semiconductor package according to example embodiments may be applied to a wafer level package. Referring to FIG. 1, a wafer 12 may include a semiconductor substrate 20 having a plurality of semiconductor chips 10. The semiconductor chips 10 may be separated from each other by chip scribe lines 14.

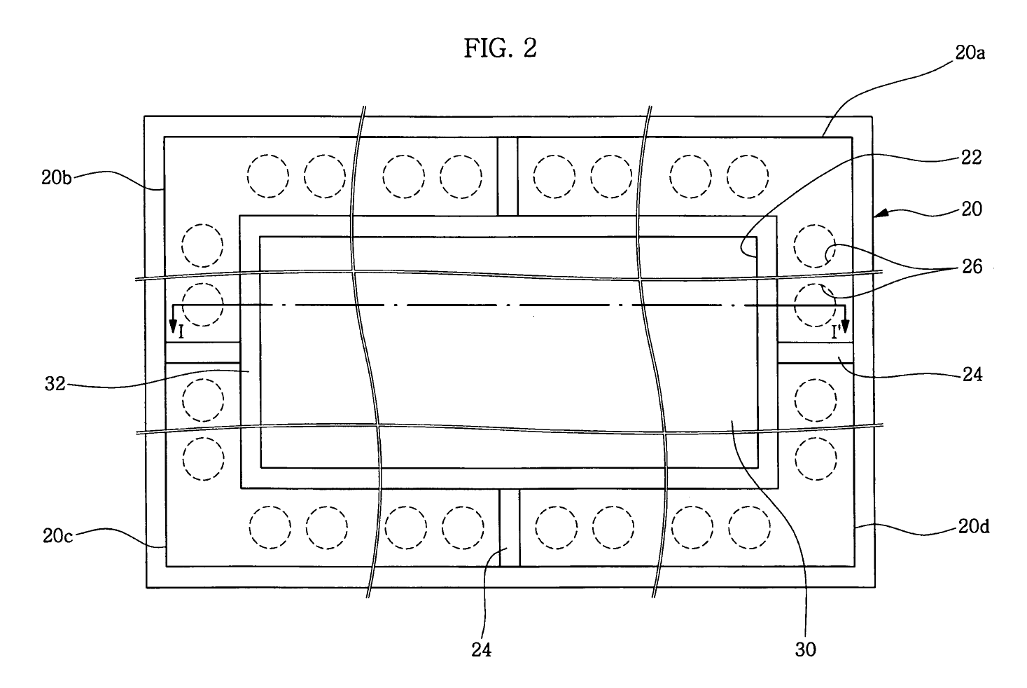

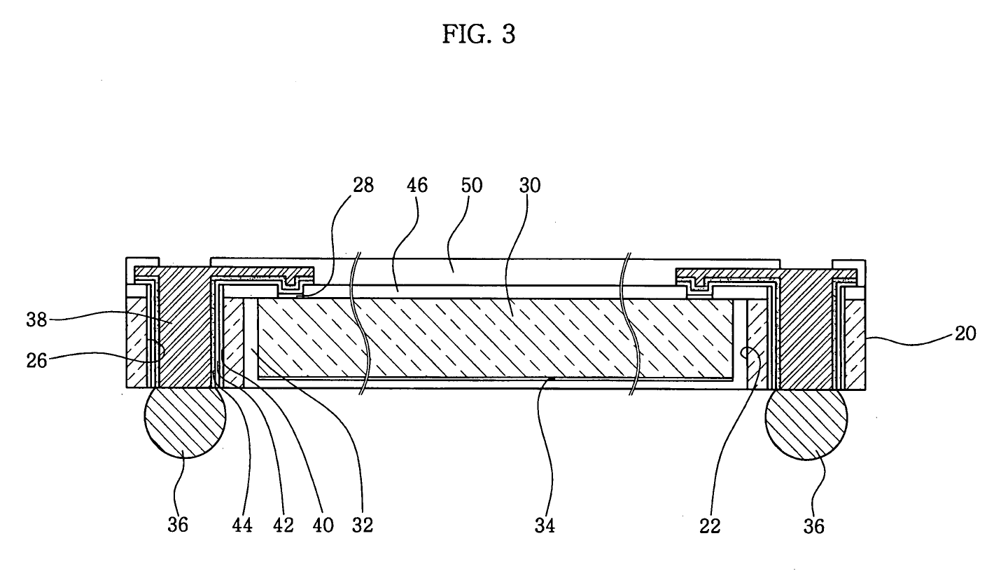

Referring to FIGS. 2 and 3, a semiconductor package according to example embodiments may include a semiconductor substrate 20 having a first through hole 22. The semiconductor substrate 20 may be composed of first to fourth sub-substrates 20a, 20b, 20c, and 20d, respectively, which surround the first through hole 22. The sub-substrates 20a, 20b, 20c, and 20d may be thermally isolated from one another. For example, thermal insulators 24 may be interposed between the sub-substrates 20a, 20b, 20c, and 20d. The thermal insulators 24 may be adhesives (e.g., silicone) and may include an insulating layer (e.g., silicon oxide layer, silicon nitride layer). Accordingly, the conduction of heat between the sub-substrates 20a, 20b, 20c, and 20d may be reduced or prevented. Therefore, the thermal insulators 24 may act as a buffer layer which may reduce or prevent the expansion of the semiconductor substrate 20 in response to externally applied heat.

Each of the first to fourth sub-substrates 20a, 20b, 20c, and 20d, respectively, may have a plurality of second through holes 26. The second through holes 26 may be aligned to surround the first through hole 22. The second through holes 26 may be spaced apart from each other.

A semiconductor chip 30 having pads 28 may be disposed in the first through hole 22. A thermal insulator 32 may be interposed between the semiconductor chip 30 and a sidewall of the first through hole 22. The thermal insulator 32 may include an insulating layer. Accordingly, the semiconductor substrate 20 and the semiconductor chip 30 may be thermally isolated from each other. Consequently, the conduction of heat generated by the semiconductor chip 30 to the sub-substrates 20a, 20b, 20c, and 20d may be reduced or prevented. Similarly, the conduction of heat generated by the sub-substrates 20a, 20b, 20c, and 20d to the semiconductor chip 30 may be reduced or prevented.

The thermal insulator 32 may be an adhesive (e.g., silicone). Accordingly, the semiconductor chip 30 may be attached to the sidewall of the first through hole 22 by the adhesive. Additionally, an adhesive tape 34 may be provided on a lower surface of the semiconductor chip 30, and the thermal insulator 32 may be formed to cover the lower surface of the semiconductor chip 30. Accordingly, when heat is applied to the semiconductor substrate 20 having the semiconductor chip 30, warping of the semiconductor chip (because of the difference between the coefficients of thermal expansion of the semiconductor chip 30 and metal interconnections adjacent to the semiconductor chip 30) may be reduced or prevented by the thermal insulator 32. Therefore, reliability of a semiconductor device may be improved by reducing or preventing the warping of a semiconductor chip having a relatively thin thickness. Additionally, thermal expansion of the semiconductor substrate 20 may be decreased, because the sub-substrates 20a, 20b, 20c, and 20d may be thermally isolated from each another, thus reducing or preventing the warping of the semiconductor chip.

A solder ball 36 may be attached to the second through holes 26. Because the second through holes 26 may be provided on each of the sub-substrates 20a, 20b, 20c, and 20d, the solder balls 36 may be thermally isolated from the semiconductor chip 30. The solder balls 36 may be disposed along an edge of the semiconductor substrate 20 so as to surround the semiconductor chip 30. Aligning the solder balls 36 along the edge of the semiconductor substrate 20 may allow the desired number of solder balls 36 to be provided even though the size of the semiconductor chip 30 may be scaled down. The solder balls 36 may be additionally disposed on a central region of the semiconductor chip 30. The solder ball 36 may be made of a metal, including Sn, Ag, Cu, and/or an alloy thereof.

The solder ball 36 may act as an external connection terminal. For example, the solder balls 36 may be disposed on a PCB (not shown). In such a case, the PCB and the semiconductor chip 30 may be thermally isolated from each other, so that a distance of neutral point (DNP) may be decreased. Therefore, defects (e.g., cracks) in the solder ball joint, because of differences in the coefficients of thermal expansion of the PCB and the semiconductor chip 30, may be reduced or prevented.

The semiconductor package according to example embodiments may have vias 38 filling the second through holes 26. The solder balls 36 may be bonded to the vias 38. The vias 38 may be a conductive layer, including a metal. An insulating layer 40 and a metal barrier layer 42 may be sequentially interposed between the sidewalls of the second through holes 26 and the vias 38. The insulating layer 40 may be a silicon oxide layer and/or a silicon nitride layer. The metal barrier layer 42 may be a titanium layer, a titanium nitride layer, a titanium tungsten layer, and/or an alloy thereof.

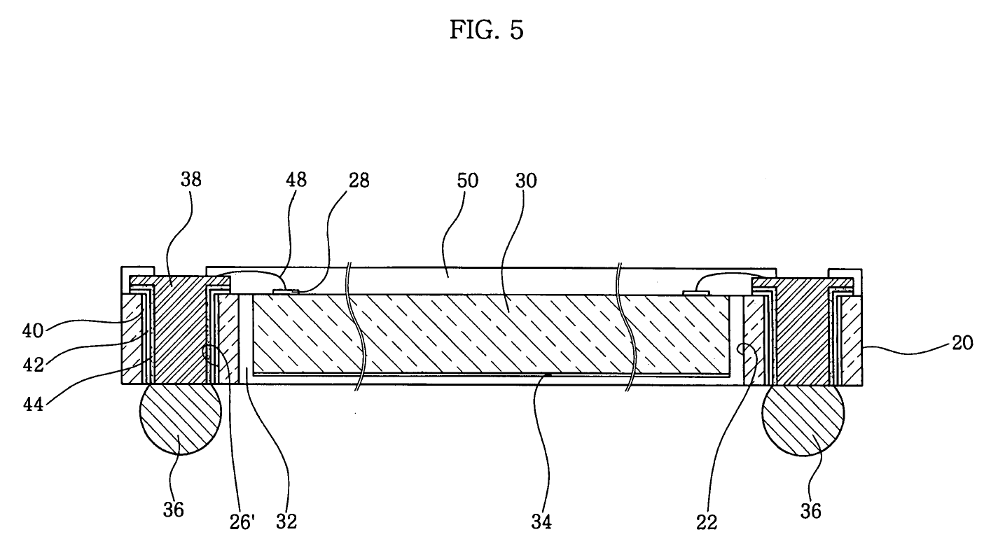

A conductive layer 44 may be interposed between the vias 38 and the metal barrier layer 42. The conductive layer 44 may be Cu, Ni, Au, and/or an alloy thereof. Redistribution traces may electrically connect the vias 38 to the pads 28. For example, the conductive layer 44 and the metal barrier layer 42 may extend so as to contact the pads 28. The vias 38 may also extend so as to contact the pads 28. An insulating layer 46 may be interposed between an upper surface of the semiconductor substrate 20 and the redistribution traces. The insulating layer 46 may be a silicon oxide layer and/or a silicon nitride layer. Alternatively, referring to FIG. 5, bonding wires 48 may electrically connect the vias 38 to the pads 28. The bonding wires 48 may be a conductive material (e.g., Au, Cu).

A passivation layer 50 may be disposed on the semiconductor substrate 20 having the semiconductor chip 30 and the vias 38. The passivation layer 50 may protect the semiconductor chip 30 and the redistribution traces. The passivation layer 50 may be an epoxy molding resin layer.

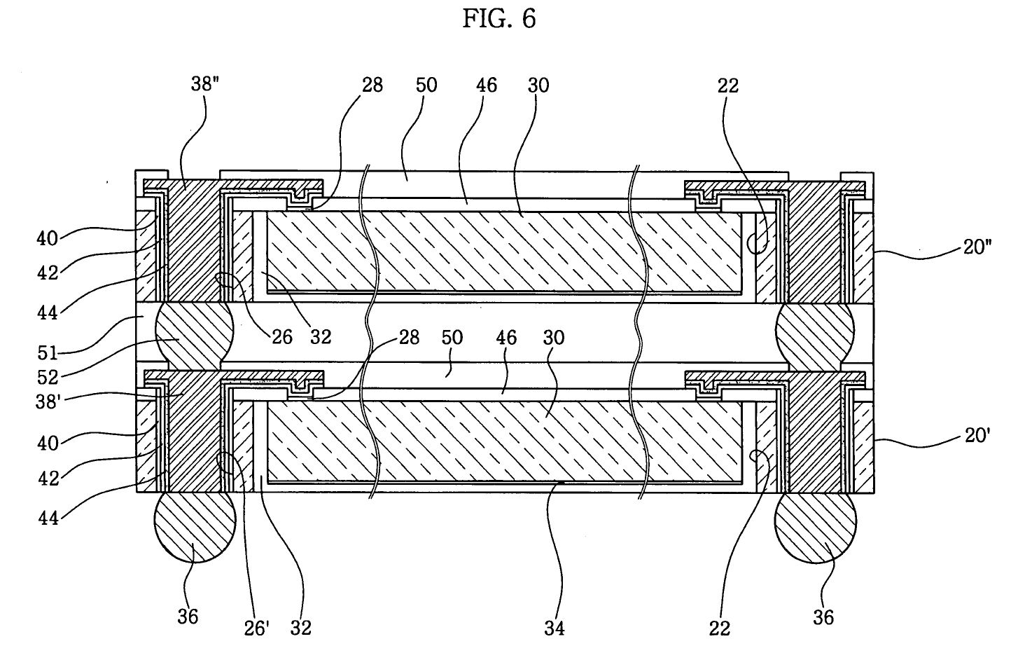

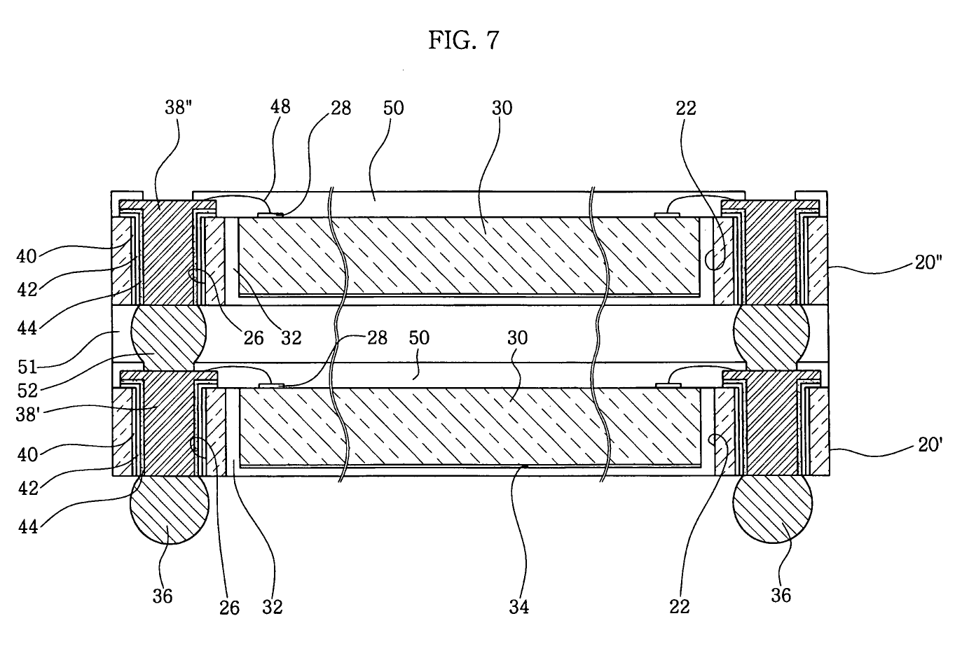

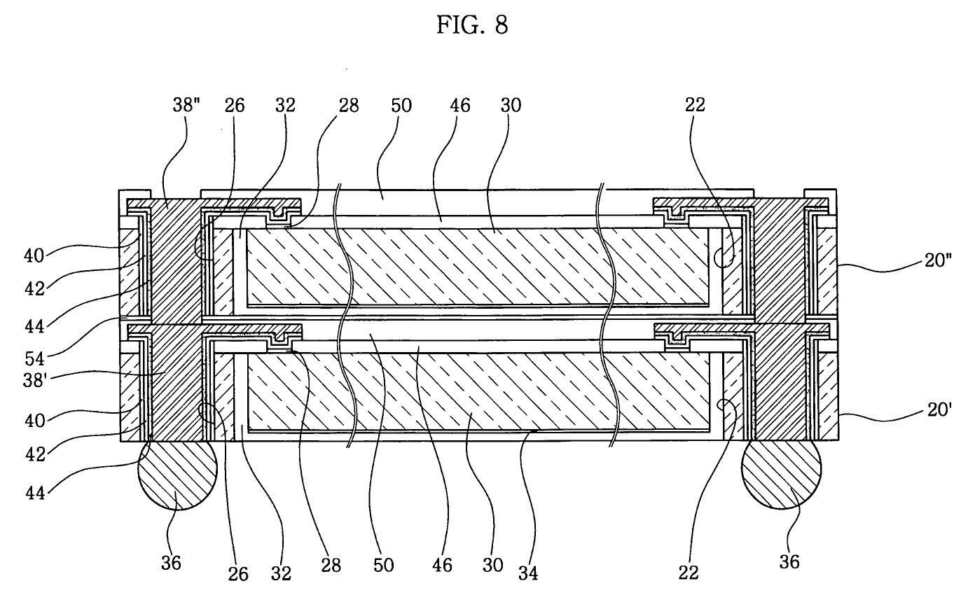

Referring to FIGS. 6 to 8, the semiconductor package according to example embodiments may be applied to a multi-chip package. For example, a plurality of semiconductor packages may be stacked. An upper semiconductor substrate 20″ may be stacked on a lower semiconductor substrate 20′ having a first lower through hole 22. The lower and upper semiconductor substrates 20′ and 20″, respectively, may be similar to the above-described semiconductor substrate 20. Referring to FIGS. 6 and 7, upper vias 38″ of the upper semiconductor substrate 20″ and lower vias 38′ of the lower semiconductor substrates 20′ may be bonded by bumps 52. For example, lower surfaces of the upper vias 38″ may be bonded to upper surfaces of the bumps 52, and upper surfaces of the lower vias 38′ may be bonded to lower surfaces of the bumps 52. The bumps 52 may be formed of a metal, including Sn, Ag, Cu, or an alloy thereof. The bumps 52 may be covered by an encapsulating resin 51. Alternatively, referring to FIG. 8, the lower and upper semiconductor substrates 20′ and 20″ , respectively, may be bonded to each other by an adhesive 54 (e.g., solder paste) without using the bumps 52. Accordingly, capacity of the semiconductor package may be increased by stacking the semiconductor package as described above.

Referring to FIG. 6, the stacked vias 38′ and 38″ and pads 28 of the semiconductor package may be connected by the above-described redistribution traces. Referring to FIG. 7, the stacked vias 38′ and 38″ and pads 28 of the semiconductor package may be connected by the above-described bonding wires 48. While the above-described multi-chip package may be formed by stacking two semiconductor substrates, additional semiconductor substrates may be stacked to achieve the desired multi-chip package.

A method of fabricating a semiconductor package according to example embodiments may be described below. Referring to FIG. 1, a silicon wafer 12 having a semiconductor substrate 20 may be prepared. The semiconductor substrate 20 may have a plurality of semiconductor chips 10. The semiconductor chips 10 may be separated from each other by chip scribe lines 14.

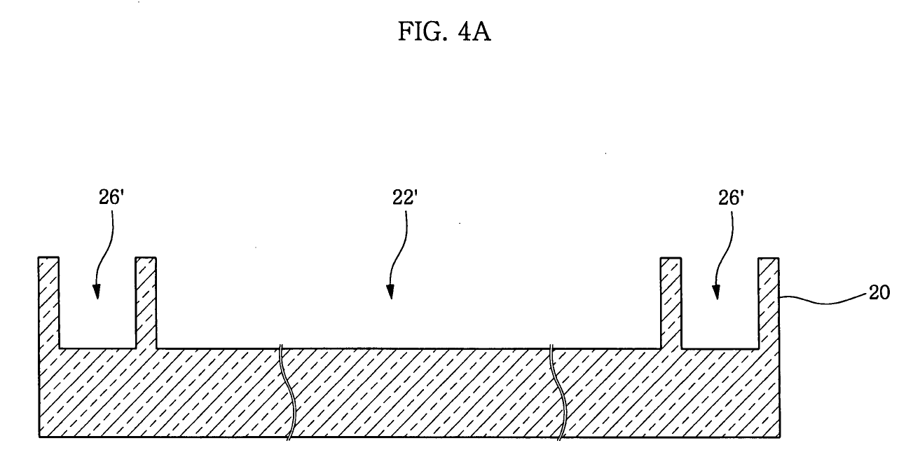

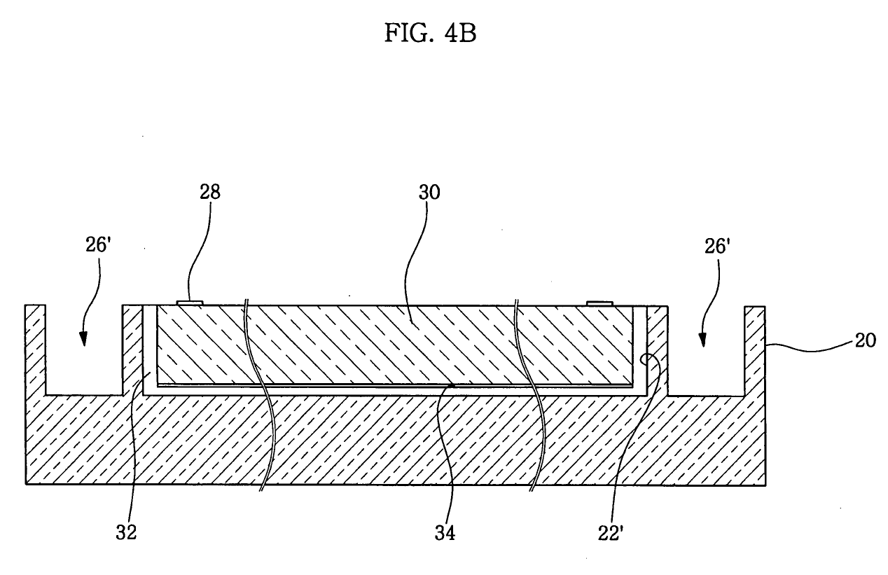

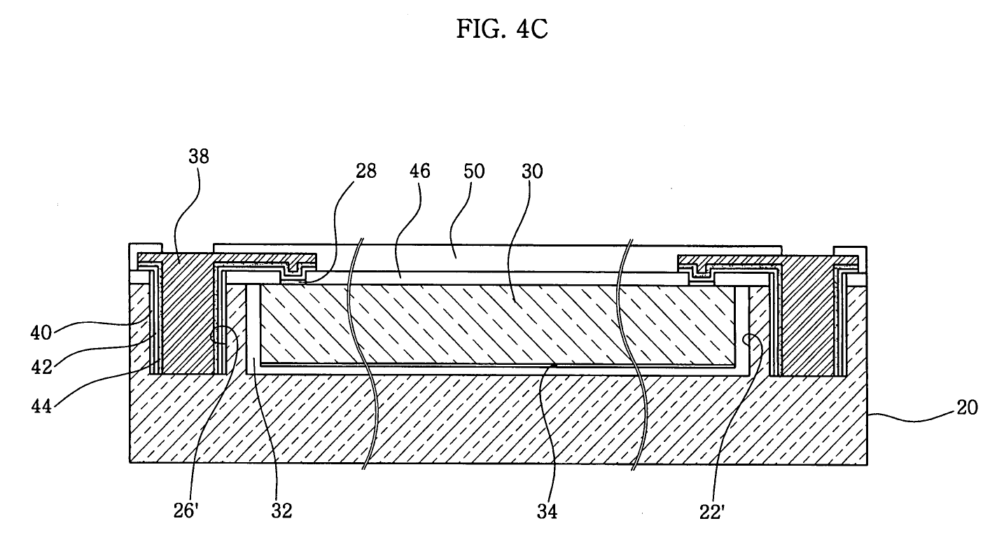

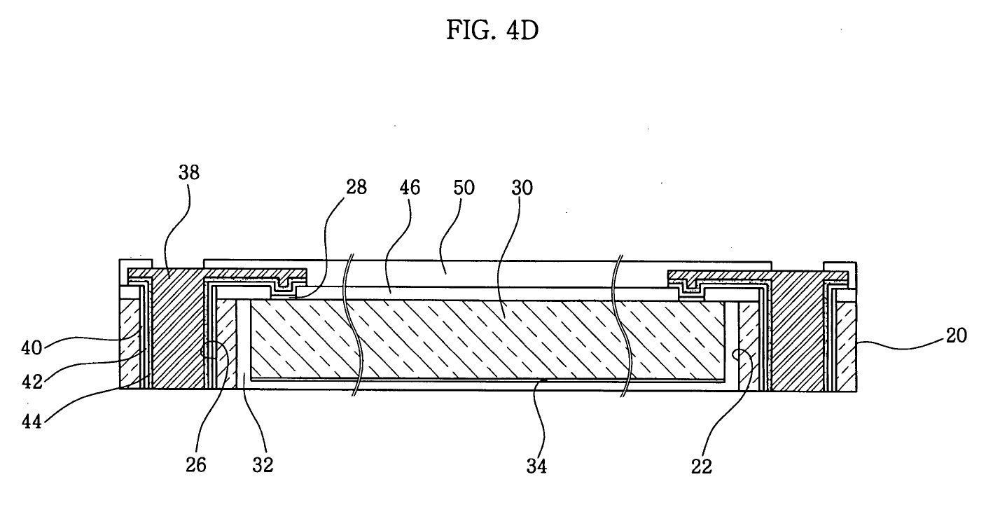

Hereinafter, it may be assumed, for purposes of illustration, that the semiconductor substrate has one semiconductor chip, although a plurality of semiconductor chips may be provided depending on the case and use. Referring to FIGS. 2 and 4A, the semiconductor substrate 20 may be patterned to form a first trench 22′ in the semiconductor substrate 20. The first trench 22′ may be formed in a central region of the semiconductor substrate 20. Additionally, the semiconductor substrate 20 may be patterned to form a plurality of second trenches 26′ surrounding the first trench 22′. For example, the second trenches 26′ may be formed along an edge of the semiconductor substrate 20. The first trench 22′ and the second trenches 26′ may be simultaneously formed.

The semiconductor substrate 20 may be composed of several sub-substrates 20a, 20b, 20c, and 20d. The sub-substrates 20a, 20b, 20c, and 20d may surround the first trench 22′. Additionally, the second trenches 26′ may be formed in each of the sub-substrates 20a, 20b, 20c, and 20d. Thermal insulators 24 may be formed between the sub-substrates 20a, 20b, 20c, and 20d. The thermal insulators 24 may be made of an adhesive, including silicone. The thermal insulators 24 may also include an insulating layer, including a silicon oxide layer and/or a silicon nitride layer. Accordingly, thermal conduction between the sub-substrates 20a, 20b, 20c, and 20d may be reduced or prevented.

Referring to FIG. 4B, a thermal insulator 32 may be formed to cover a sidewall and a bottom of the first trench 22′. The thermal insulator 32 may be made of an adhesive (e.g., silicone). A semiconductor chip 30 having pads 28 may be provided in the first trench 22′. Accordingly, the semiconductor chip 30 may be attached to the sidewall and bottom of the first trench 22′ by the adhesive. An adhesive tape 34 may also be formed on a lower surface of the semiconductor chip 30.

Referring to FIG. 4C, an insulating layer 40 may cover a sidewall of the second trench 26′. The insulating layer 40 may be made of a silicon oxide layer and/or a silicon nitride layer. A metal barrier layer 42 may cover the insulating layer 40. The metal barrier layer 42 may be made of a titanium layer, a titanium nitride layer, a titanium tungsten layer, and/or an alloy thereof. The metal barrier layer 42 may be formed by electroplating or sputtering. A conductive layer 44 may be formed to cover the metal barrier layer 42. The conductive layer 44 may be made of a metal layer, including Cu, Ni, Au, and/or an alloy thereof. The conductive layer 44 may act as a seed layer. The conductive layer 44 may be formed by electroplating or sputtering.

A redistribution trace may electrically connect the conductive layer 44 to the pads 28. For example, the metal barrier layer 42 and the conductive layer 44 may extend so as to contact the pads 28. An insulating layer 46 may be formed to cover the substrate 20 before forming the redistribution trace. The insulating layer 46 may be patterned to expose the pads 28 and the second trenches 26′. Alternatively, in lieu of the redistribution trace, bonding wires 48 may electrically connect the pads 28 to the conductive layers 44.

Vias 38 may be formed to fill the second trenches 26′. The vias 38 may extend so as to be electrically connected to the pads 28. The vias 38 may be made of a conductive material (e.g., metal). The vias 38 may be formed by sputtering or chemical vapor deposition (CVD). A passivation layer 50 may be formed on the semiconductor substrate 20 having the vias 38. The passivation layer 50 may be made of an epoxy molding resin layer. The passivation layer 50 may be patterned to expose at least a portion of the vias 38.

Referring to FIG. 4D, a lower portion of the semiconductor substrate 20 having the semiconductor chip 30 and the vias 38 may be polished so as to expose the first trench 22′ and the second trenches 26′. The polishing process may be performed by a chemical-mechanical polishing technique or a wet etching technique. Accordingly, an end portion of the conductive layer 44, lower surfaces of the vias 38, and a lower surface of the thermal insulator 32 may be exposed. Additionally, first and second through holes 22 and 26, respectively, may be formed. Referring to FIG. 3, one or more solder balls 36 may be formed so as to be in contact with the exposed end portion of the conductive layer 44 and/or the exposed lower surfaces of the vias 38.

By forming solder balls on a semiconductor substrate composed of sub-substrates which are thermally isolated from one another, the reliability of the solder ball joints may be improved. A semiconductor chip and a semiconductor substrate may also be thermally isolated so as to reduce or suppress the warping of the semiconductor substrate caused by the difference between the coefficients of thermal expansion of the semiconductor chip and the semiconductor substrate. Furthermore, an adhesive may be formed between the semiconductor substrate and the lower surface of the semiconductor chip so as to reduce or prevent the warping of the semiconductor substrate.

While example embodiments have been disclosed herein, it should be understood that other variations may be possible. Such variations are not to be regarded as a departure from the spirit and scope of example embodiments of the present disclosure, and all such modifications as would be obvious to one skilled in the art are intended to be included within the scope of the following claims.

What is claimed is:

1. A semiconductor package, comprising:
a semiconductor substrate having a first through hole and a plurality of second through holes;
a semiconductor chip in the first through hole, the semiconductor chip having a plurality of pads; and
a solder ball at an end portion of at least one of the plurality of second through holes and electrically connected to at least one of the plurality of pads.

2. The semiconductor package of claim 1, wherein the plurality of second through holes surround the first through hole.

3. The semiconductor package of claim 1, further comprising:
a conductive layer on a sidewall of at least one of the plurality of second through holes and electrically connected to at least one of the plurality of pads and the solder ball.

4. The semiconductor package of claim 3, further comprising:
a redistribution trace connecting the conductive layer to at least one of the plurality of pads.

5. The semiconductor package of claim 3, further comprising:
a bonding wire connecting the conductive layer to at least one of the plurality of pads.

6. The semiconductor package of claim 1, further comprising:
conductive vias filling the plurality of second through holes and electrically connected to at least one of the plurality of pads and the solder ball.

7. The semiconductor package of claim 1, further comprising:
a first thermal insulator between the semiconductor chip and a sidewall of the first through hole.

8. The semiconductor package of claim 7, wherein the first thermal insulator includes an adhesive.

9. The semiconductor package of claim 8, wherein the adhesive extends to cover a lower surface of the semiconductor chip.

10. The semiconductor package of claim 1, wherein the semiconductor substrate includes first to fourth sub-substrates surrounding the first through hole and second thermal insulators between the first to fourth sub-substrates, each of the first to fourth sub-substrates having at least one of the plurality of second through holes.

11. The Semiconductor package of claim 1, further comprising:
an upper semiconductor substrate on the semiconductor substrate, the upper semiconductor substrate having a first upper through hole and a plurality of second upper through holes; and
an upper semiconductor chip in the first upper through hole, the upper semiconductor chip having a plurality of upper pads,
wherein at least one of the plurality of upper pads is electrically connected to the solder ball.

12. The semiconductor package of claim 11, wherein the second upper through holes surround the first upper through hole.

13. The semiconductor package of claim 11, further comprising:
an upper conductive layer on a sidewall of at least one of the plurality of second upper through holes and electrically connected to at least one of the plurality of upper pads.

14. The semiconductor package of claim 13, further comprising:
an upper redistribution trace connecting the upper conductive layer to at least one of the plurality of upper pads.

15. The semiconductor package of claim 13, further comprising:
an upper bonding wire connecting the upper conductive layer to at least one of the plurality of upper pads.

16. The semiconductor package of claim 11, further comprising:
lower conductive vias filling the plurality of second through holes and electrically connected to at least one of the plurality of pads and the solder ball; and
upper conductive vias filling the plurality of second upper through holes and electrically connected to at least one of the plurality of upper pads and the lower conductive vias.

17. The semiconductor package of claim 16, further comprising:
bumps between and in contact with the upper conductive vias and the lower conductive vias.

18. The semiconductor package of claim 11, further comprising:
a first upper thermal insulator between the upper semiconductor chip and a sidewall of the first upper through hole.

19. The semiconductor package of claim 18, wherein the first upper thermal insulator includes an upper adhesive.

20. The semiconductor package of claim 19, wherein the upper adhesive extends to cover a lower surface of the upper semiconductor chip.

21. The semiconductor package of claim 11, wherein the upper semiconductor substrate includes first to fourth upper sub-substrates surrounding the first upper through hole and second upper thermal insulators between the first to fourth upper sub-substrates, each of the first to fourth upper sub-substrates having at least one of the plurality of second upper through holes.

22. A method of fabricating a semiconductor package, comprising:
preparing a semiconductor substrate;
forming a first through hole and a plurality of second through holes in the semiconductor substrate;
providing a semiconductor chip in the first through hole, the semiconductor chip having a plurality of pads; and
forming a solder ball at an end portion of at least one of the plurality of second through holes, the solder ball electrically connected to at least one of the plurality of pads.

23. The method of claim 22, wherein the plurality of second through holes surround the first through hole.

24. The method of claim 22, wherein forming the first through hole and the plurality of second through holes includes:
patterning an upper surface of the semiconductor substrate to provide a first trench and a plurality of second trenches surrounding the first trench; and
polishing a lower surface of the semiconductor substrate so as to expose the first trench and the plurality of second trenches.

25. The method of claim 24, further comprising:
forming a first thermal insulator covering a bottom and a sidewall of the first trench; and
providing the semiconductor chip in the first trench prior to polishing the lower surface of the semiconductor substrate.

26. The method of claim 25, wherein the first thermal insulator is made of an adhesive.

27. The method of claim 24, further comprising:
forming a first conductive layer so as to cover a sidewall of the plurality of second trenches; and
forming a second conductive layer so as to fill the plurality of second trenches prior to polishing the lower surface of the semiconductor substrate.

28. The method of claim 27, further comprising:
forming a redistribution trace or a bonding wire to connect at least one of the plurality of pads to the first conductive layer.

29. The method according to claim 22, wherein preparing the semiconductor substrate includes:
forming first to fourth sub-substrates surrounding the first through hole; and
forming a second thermal insulator between the first to fourth sub-substrates, each of the first to fourth sub-substrates having at least one of the plurality of second through holes.
